(19) United States
(12) Patent Application Publication
(10) Pub. No.: US 2011/0229707 A1
(43) Pub. Date: Sep. 22, 2011

(54) METHOD OF MANUFACTURING SINGLE CRYSTAL INGOT AND WAFER MANUFACTURED BY THEREBY

(76) Inventor: Young-Ho Hong, Seoul (KR)

(21) Appl. No.: 13/019,069

(22) Filed: Feb. 1, 2011

(30) Foreign Application Priority Data
Mar. 16, 2010 (KR) 10-2010-0023158

(51) Int. Cl. C30B 15/20; B32B 3/00; B32B 3/26

(52) U.S. Cl. 428/315.7; 117/35; 428/336

(57) ABSTRACT

A method of manufacturing single crystal ingot and a wafer manufactured thereby are provided. The method includes pulling and growing an ingot in a crucible; and cooling the ingot, wherein during the pulling of the ingot, a pulling rate of the ingot is configured to generate a vacancy of less than 80 nm; when the ingot is cooled at an interval of about 1000 to about 2000, a cooling speed of the ingot is slow cooling to allow the vacancy of less than about 80 nm to grow into a vacancy of more than about 80 nm.

### CROSS-REFERENCE TO RELATED APPLICATION

This application claims the priority benefit of Korean patent application number 10-2010-0023158 filed Mar. 16, 2010, which is hereby incorporated by reference.

### BACKGROUND OF THE INVENTION

1. Field of the Invention

The present disclosure relates to a method of manufacturing single crystal ingot and a wafer manufactured thereby.

2. Description of the Related Art

Semiconductor device manufacturing processes have limitations in formation of bulk micro defect (BMD) because oxygen precipitation nuclei do not grow adequately during a low temperature process due to a low temperature of a high integration process. For this reason, it is regarded as difficult to provide sufficient intrinsic gathering ability to a wafer during a low temperature device manufacturing process.

In relation to the BMD, point defect and oxygen according to a growth history are included in a silicon single crystal during a silicon single crystal growth process. This contained oxygen grows as oxygen precipitates by heat applied during a manufacturing process of a semiconductor device, and in that way, enhances the strength of a silicon wafer and serves as an intrinsic gathering site, which have beneficial properties and also have harmful properties that may cause leakage current and defects of a semiconductor device.

Accordingly, according to a related art predetermined BMD formation, a denuded zone (DZ) layer without oxygen precipitates is formed with a predetermined depth from a wafer surface in a depth direction.

Due to this, in order to obtain proper BMD concentration, an attempt for doping a third element such as nitrogen or carbon to increase BMD concentration according to a point defect concentration control has been made. However, this method may be effective in increasing a BMD level but cause quality changes such as minority-carrier diffusion length (MCDL) and becomes a factor for leakage current if carbon is doped more than a proper level. Of all things, since it is difficult to obtain a DZ layer due to BMD concentration increase, an additional process such as high temperature thermal treatment is required, such that manufacturing cost is inevitably increased because of productivity deterioration.

Moreover, according to a related art, another method for controlling BMD concentration adjusts a level of initial oxygen concentration. However, in case of required BMD concentration with respect to oxygen concentration, it exceeds a predetermined oxygen concentration.

In another example, a related art has productivity deterioration due to a pulling rate's deterioration if the BMD and DZ layers are controlled and gate oxide integrity (GOI) of a wafer surface region is manufactured with an excellent non-defective wafer at the same time.

### SUMMARY OF THE CLAIMED INVENTION

Embodiments provide a single crystal ingot manufacturing method and a wafer manufactured thereby. The method provides excellent device yield with distribution of uniform vacancy defect and denuded zone (DZ) through bulk micro defect (BMD) level control required in a semiconductor device process.

In one embodiment, a method of manufacturing a single crystal ingot includes: pulling and growing an ingot in a crucible; and cooling the ingot, wherein during the pulling of the ingot, a pulling rate of the ingot is configured to generate a vacancy of less than 80 nm; when the ingot is cooled at an interval of about 1000° C. to about 2000° C., a cooling speed of the ingot is slow cooling to allow the vacancy of less than about 80 nm to grow into a vacancy of more than about 80 nm.

In another embodiment, a wafer has a uniform bulk micro defect (BMD) level in a radial direction of the wafer and includes a denuded zone (DZ) of more than about 10 μm.

### BRIEF DESCRIPTION OF THE DRAWINGS

FIG. 1 is a BMD level view of a wafer according to an embodiment and comparative example.

FIGS. 2 and 3 are GOI characteristic views of a wafer according to a comparative example.

FIGS. 4 and 5 are GOI characteristic views of wafer according.

FIGS. 6 and 7 are graphs illustrating a thermal history curve and a cooling speed curve in a single crystal manufacturing method.

FIGS. 8 and 9 are views illustrating point defect distribution of a wafer manufactured by a single crystal manufacturing method.

FIG. 10 is a view illustrating a DZ level of a wafer manufactured by a single crystal manufacturing method.

FIG. 11 is a view illustrating data of near surface micro defect (NSMD) of the center and edge of a wafer manufactured by a single crystal manufacturing method.

### DETAILED DESCRIPTION

In the descriptions of embodiments, it will be understood that when a layer (or film), a region, a pattern, or a structure is referred to as being ‘on/above/over/upper’ substrate, each layer (or film), a region, a pad, or patterns, it can be directly on substrate each layer (or film), the region, the pad, or the patterns, or intervening layers may also be present. Further, it will be understood that when a layer is referred to as being ‘under/below/lower’ each layer (film), the region, the pattern, or the structure, it can be directly under another layer (film), another region, another pad, or another patterns, or one or more intervening layers may also be present. Therefore, meaning thereof should be judged according to the spirit of the present disclosure.

In the figures, a dimension of each of elements may be exaggerated for clarity of illustration, and the dimension of each of the elements may be different from an actual dimension of each of the elements. Not all elements illustrated in the drawings must be included and limited to the present disclosure, but the elements except essential features of the present disclosure may be added or deleted.

Embodiments provide a single crystal ingot manufacturing method and a wafer manufactured thereby. The method provides excellent device yield with distribution of uniform vacancy defect and denuded zone (DZ) through bulk micro defect (BMD) level control required in a semiconductor device process.

As a semiconductor device process is miniaturized in a nano level, in order to improve GOI characteristic, a region is divided into a vacancy-region in particular and an interstitial region according to an pulling rate during a silicon single crystal growth and there is a non-defective region with no deficiency and surplus of electrons based on oxidation induced stacking fault (OSF) between the two regions.

Moreover, a bulk micro defect (BMD) level having a close relation to intrinsic getting ability is determined by initial oxygen concentration and thus an additional thermal treatment process is inevitable to obtain high BMD in a low oxygen concentration typically.

Moreover, although an issue for increasing BMD in an oxygen concentration of a specific region is raised in order to meet a BMD level of various demands according to a device, there is a method for improving BMD but almost no method for suppressing BMD according to a related art. Even when there is any method that suppresses BMD through a low temperature processes, an additional thermal treatment is inevitably required.

Accordingly, according to the a single crystal ingot manufacturing method and a wafer manufactured thereby, in relation to a level of a point defect that may be problematic, through a fast pulling rate and crystal cooling thermal history control (slow cooling), concentration and size (a critical small size that affects GOI) of a vacancy defect grows into a large size through diffusion and condensation, such that productivity can be increased and GOI properties can be improved, while allowing a new technique (e.g., BMD suppression technique) to be applied to an in-situ process. As a result, according to a BMD level required by various devices, BMD concentration control is possible without doping a third element such as nitrogen or carbon or additional following thermal treatment process. Thus, a wafer having a uniform point defect in a wafer's radius direction can be manufactured. Therefore, manufacturing cost can be drastically decreased and a yield of a semiconductor device can be improved.

Accordingly, according to the a single crystal ingot manufacturing method and a wafer manufactured thereby, an pulling rate during silicon single crystal growth allows oxygen stacked layer defective ring to exist around an ingot or fall into the outside and constitutes a hot zone of a growing crystal thermal history (which allows a temperature interval of about 1000° C. to about 1,200° C. where a vacancy is generated and grow to be slowly cooled). If an ingot is grown and cut to be processed as a wafer after increasing thermal history uniformity in an ingot radius direction by adjusting cooling conditions, vacancy defects formed through slow cooling effect grows through diffusion and condensation and thus uniformly exist in a wafer radius direction.

A vacancy defect size that affects GOI (Tox, a thickness of an oxide layer disposed on a Si wafer during measurement, about 120 Å base) is regarded as an about 10 nm to 80 nm level, and it is identified that GOI fail occurs significantly if a vacancy concentration of a corresponding size is high according to an embodiment.

Furthermore, while GOI is measured, Tox may vary and may be based on about 100 Å to about 120 Å. This means that the affecting vacancy size may vary if Tox is changed (for example, 75 Å or 200 Å). As Tox is thicker, the vacancy size should be larger and as Tax is thinner, the vacancy size may shift to a small size.

In a related art, improvement for removing vacancy defect to prevent GOI fail is made. On the other hand, embodiments select and control a GOI killer size, so that a vacancy concentration may be adjusted with a pulling rate and vacancy may grow with respect to an induced point defect through crystal thermal history cooling effect. Therefore, if a vacancy size distributed in a 10 nm to 80 nm level (more than 50% of related art) is controlled in a wafer radius direction with 80 nm to 200 nm of at least more than 40%, it is confirmed that GOI characteristics can be improved.

Moreover, the silicon wafer to which slow cooling effect is applied according to high speed growth and crystal thermal history control of the embodiments represents different properties from a typical silicon wafer due to point defect concentration and size change and may form a lower BMD than the same initial oxygen concentration due to reaction of coarse vacancy defect in a radius direction and oxygen precipitate formed in the vacancy defect especially in case of BMD. This allows a BMD level to be excessively high such that obtaining of a DZ layer becomes difficult in case of a silicon wafer of high oxygen concentration (required oxygen concentration, for example, 10-19 ppma, preferably 11-18 ppma, more preferably 12˜17) and therefore, this requires additional processes such as subsequent thermal process such that manufacturing cost is inevitably increased.

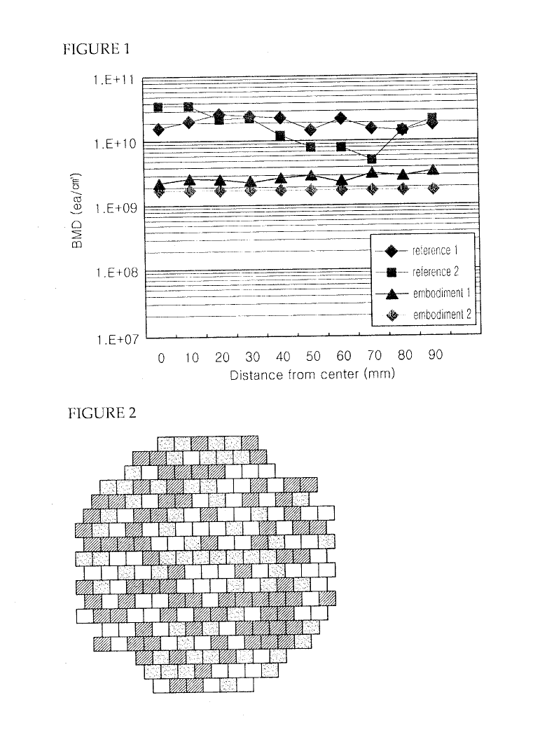

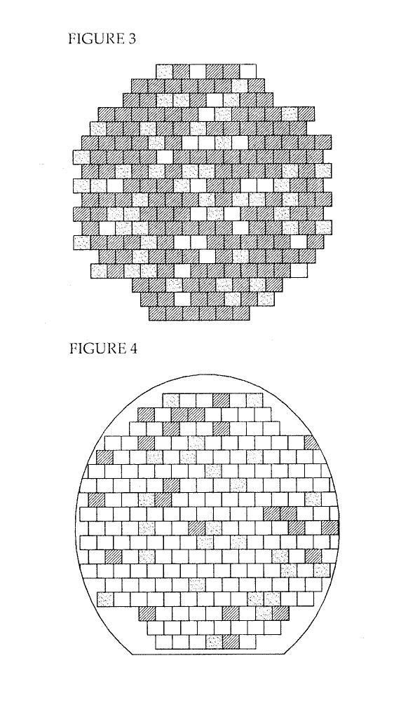

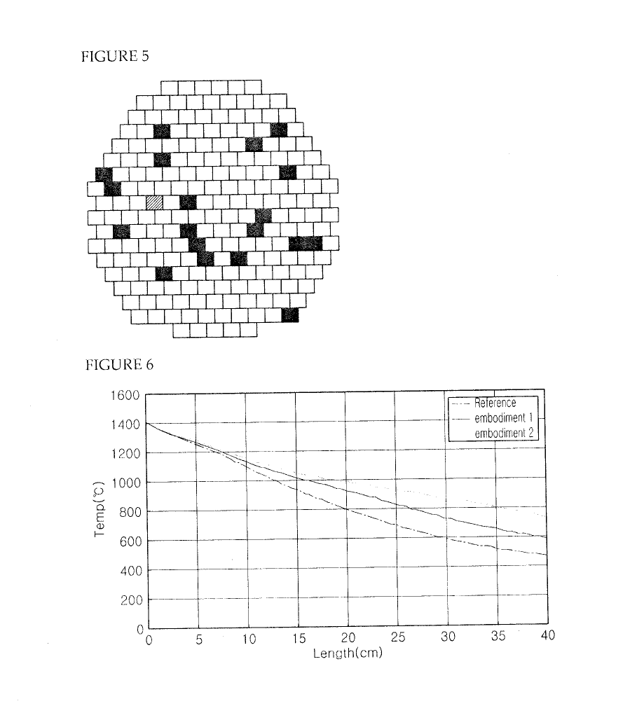

FIG. 1 is a view illustrating a BMD level example of a wafer according to an embodiment and comparative example. FIGS. 2 and 3 are views illustrating GOI characteristic examples according to first and second comparative examples. FIGS. 4 and 5 are GOI characteristic examples according to first and second comparative examples.

Referring to FIGS. 2 through 5, portions indicated with gray color or doted area are processed as fail due to poor GOI characteristics and it is confirmed that the first and second embodiments (FIGS. 4 and 5) have a higher yield than the comparative examples (FIGS. 2 and 3).

The first comparative example, as a silicon wafer grown in a related art typical cusp magnetic system, without slow cooling of the crystal center and edge, or as a result of a state maintaining a temperature gradient different between the center and the edge to be more than 30°, a BMD level, and GOI (TZDB) with respect to a silicon wafer having an initial oxygen concentration of about 13 ppma, shows a BMD level proportional compared to the initial oxygen concentration but excessive BMD formation. Due to irregularity in a radius direction and vacancy defect of a small size, a GOI yield is low.

The second comparative example, as a result about a BMD level and GOI characteristic according to a high speed increase without slow cooling effect, controls an initial oxygen concentration of about 13 ppma under the same conditions as the first comparative example and in case of a silicon wafer where only point defect concentration becomes higher according to a high speed pulling rate without slow cooling effect of a crystal, BMD behavior is similar to the comparative example and due to generation of vacancy defect of excessively small size that affects a GOI obtaining rate, GOI yield becomes lower.

The first and second embodiments are results of BMD level control and GOI obtained with slow cooling effect and growth of vacancy defect through crystal thermal history control.

According to an embodiment, in case of a silicon wafer of about 11 ppma obtained through point defect generation with a high speed increase and slow cooling effect through thermal history control, a BMD level is lower compared to the first and second comparative examples and this shows that due to vacancy growth with slow cooling effect, an initial oxygen concentration ratio is appropriately controlled, vacancy generated through sufficient slow cooling effect grows into a size that does not affect the GOI fail as growth through diffusion and condensation.

FIGS. 6 and 7 illustrate thermal history curve and cooling speed curves in a single crystal manufacturing method according to embodiment.

In order to achieve effects of embodiments, slow cooling effect for crystal thermal history control, when passing through a cooling speed of crystal, especially, COP formation interval, a cooling speed ΔT of crystal thermal history at about 1200° C. to about 1000° C. is less than at least about 30° C./cm, represent the same result as the first and second embodiments.

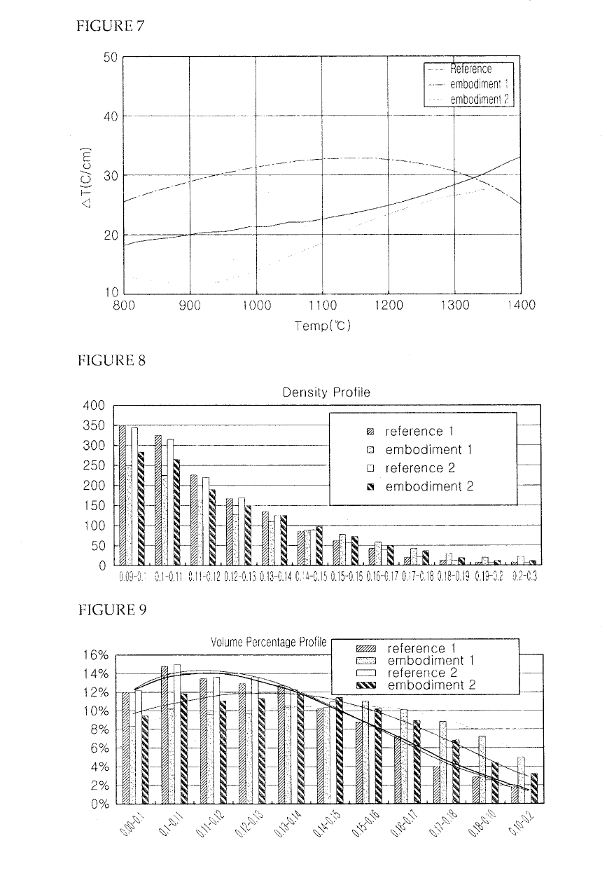

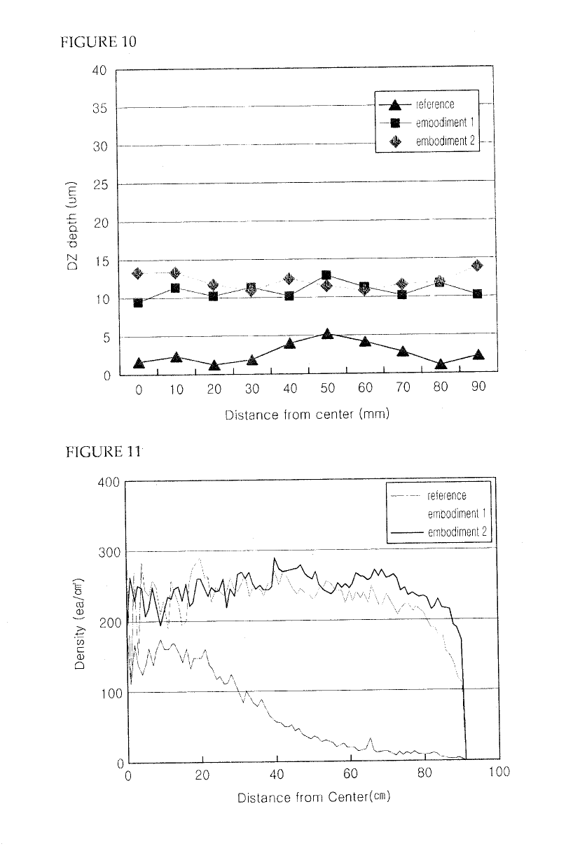

FIGS. 8 and 9 are pint defect distribution manufactured by controlling a thermal history of crystal through a single crystal manufacturing method according to an embodiment.

It is confirmed that as shown in silicon wafer's point defect distribution and BMD distribution manufactured by the first and second embodiments, vacancy concentration is uniformly distributed in a radius direction.

FIGS. 8 and 9, as a related art, after causing point defect by pulling rate, according to the first and second comparative embodiments of point defect without slow cooling, simultaneously causing point defect generation according to a high speed pulling rate and through growth such as diffusion and condensation of point defect by slow cooling effect, when crystal growth is made, illustrate distribution of point defect.

As shown in FIGS. 8 and 9, it is confirmed that point defects of a small size in the first and second comparative examples shift to the right, based on this result, it is confirmed that point defect with a small size (for example, 10 nm to 80 nm) grows into one with a large size (for example, 80 to 200 nm) through diffusion and condensation and the BMD level is suppressed through reaction with oxygen. In the GOI result, it is confirmed that GOI yield is improved by controlling a critical small size that causes fail.

FIG. 10 is a DZ level example of a wafer manufactured by a single crystal manufacturing method according to an embodiment.

The wafer manufactured according to an embodiment represents a uniform BMD level in a radius direction and also the DZ of more than a proper level can be obtained such that it is confirmed that IG ability acquisition and sufficient DZ acquisition for pattern recognition are possible in a semiconductor device process.

TABLE 1

| | Center cooling | Edge cooling | Center and edge |
|---|---|---|---|
| | speed (ΔT) | speed (ΔT) | cooling speed |
| | (° C./cm) | (° C./cm) | difference (° C./min) |
| Comparative | 30 | 34 | 5 |
| example | | | |
| First embodiment | 26 | 24 | 2 |
| Second | 20 | 21 | 1 |
| embodiment | | | |

Table 1 shows process condition and result summarized contents according to a comparative example and first and second embodiments.

In more detail, with respect to about 1000° C.˜1200° C. interval, when silicon single crystal grows suggested by an embodiment, cooling speed and its difference at the center and edge of crystal are shown in table 1.

In case of a related art (a comparative example), it is identified that a cooling speed is fast and a cooling speed difference of the center and edge is increased. As a point defect distribution, point defects caused by a fast cooling speed of the edge do not grow sufficiently and remain in a micro size. As a result, concentration becomes lower and due to an uneven distribution in a wafer radius direction, quality property such as DZ or BMD becomes uneven.

On the other hand, according to crystal through slow cooling as shown in the first and second embodiments, entire crystal's cooling speed is slow and cooling speed difference of the center and edge is small. Thus, by giving sufficient time for diffusion and growth to the generated point defect, uniform distribution in a wafer radius direction and D2 of a proper level acquisition and BMD level control are possible.

Next, method details of a process for controlling a cooling speed difference of the center and edge are described according to an embodiment.

According to an embodiment, by adjusting a pulling speed (PS) to generate a vacancy, the embodiment may configure the PS in a range of about 0.7 mm/min to about 0.90 mm/min and as in this case, speed is faster and vacancy is generated significantly.

Moreover, if the PS is configured in the above range, a vacancy of small size of less than 80 nm is plentiful and this affects adversely on GOI, therefore, this embodiment lowers a cooling speed at a predetermined temperature interval and performs slow cooling.

For example, through a design change of a heat sink such as an insulator in a NOP, the inside of a single crystal grower (that is, an ingot peripheral) is heated and slow cooling is performed ultimately at an about 1000° C. to 1200° C. interval, such that control is possible for a large size (for example, 80 to 200 nm size) through diffusion, condensation, and growth of a vacancy in crystal.

According to an embodiment, since there is an oxygen precipitate formation temperature interval at a 900° C. interval called oxidation-induced stacking fault ring (OiSF), fast cooling should be made at this interval and this affects adversely on OiSF or GOI. Therefore, if slow cooling is made simply, it affects crystal thermal history of 1000° C.˜1200° C. and 900° C. interval and due to OiST formation, GOI fail may occur.

According to the embodiment, heat sink, for example, assuming an entire size of NOP as 100%, as a percentage that the inner insulator occupies is configured with about 10% to 70%, that is, an empty space in the insulator is configured with an about 90% to 30% range, the crystal's overall cooling speed is slowly progressed and a cooling speed difference of the center and the edge is small, such that the generated point defect is given with sufficient time for diffusion and growth. Therefore, uniform distribution is given in a wafer radius direction and D2 acquisition of a proper level is obtained and BMD level control is possible.

Furthermore, if a percentage that the insulator occupies in the heat sink is less than 10%, abnormal growth such as flower in crystal growth may occur. If more than 70%, a vacancy in the crystal remains mostly in a small size. Thus, its effect becomes less.

FIG. 11 illustrates data of near surface micro defect (NSMD) of the center and edge of a wafer manufactured by a single crystal manufacturing method according to an embodiment.

According to FIG. 11, in relation to the first and second embodiments manufactured by the single crystal manufacturing method, compared to a comparative example, it is confirmed that near surface micro defects of the center and edge are uniform.

According to a wafer manufactured by a single crystal ingot manufacturing method and a wafer manufactured thereby, by increasing thermal history uniformity in a crystal and radius direction to grow and cut ingot and then processing the ingot as a wafer, vacancy defect formed by slow cooling effect uniformly is distributed in a wafer radius direction through diffusion and condensation.

Furthermore, a yield of GOI having no defect can be improved by controlling point defect caused by the slow cooling effect and oxygen precipitate is controllable without an additional thermal treatment process for forming a bulk micro defect (BMD). As a result, excellent device yield can be anticipated

Embodiments relate to a single crystal ingot manufacturing method and a wafer manufactured thereby.

According to a single crystal manufacturing method and a wafer manufactured thereby, after thermal history uniformity in a crystal and radius direction is increased to grow and cut an ingot, the ingot is processed as a wafer. Vacancy defect formed through slow cooling effect is uniformly distributed in a wafer radius direction through diffusion and condensation.

Furthermore, according to an embodiment, a yield of GOI with no defect can be improved by controlling point defects caused through the slow cooling effect and oxygen precipitates are controllable without an additional thermal treatment process for forming a bulk micro defect (BMD). As a result, excellent device yield can be anticipated.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a single crystal ingot, the method comprising:
pulling and growing an ingot in a crucible; and
cooling the ingot, wherein during the pulling of the ingot, a pulling rate of the ingot is set to generate a vacancy of less than 80 nm, and when the ingot is cooled at an interval of about 1000° C. to about 2000° C., a cooling speed of the ingot is set to slow cooling to allow the vacancy of less than about 80 nm to grow into a vacancy of more than about 80 nm.

2. The method of claim 1, wherein the pulling rate of the ingot is set to be in a range of about 0.7 mm/min to about 0.90 mm/min.

3. The method of claim 1, wherein during the cooling of the ingot, a cooling speed (/cm) difference between the center and edge of the ingot is less than about 3/cm.

4. The method of claim 3, wherein each of the cooling speed (/cm) at the center and the edge of the ingot is less than about 30/cm.

5. The method of claim 3, further comprising a heat sink between the crucible and the ingot.

6. The method of claim 5, wherein if an entire area of the heat sink is assumed as 100%, a percentage that an insulator in the heat sink occupies is set to be in a range of about 10% to about 70%.

7. The method of claim 5, wherein if an entire area of the heat sink is assumed as 100%, a percentage that an insulator in the heat sink occupies is set to be in a range of about 10% to about 70% and a cooling speed difference between the center and edge of the ingot is controlled to be less than about 3/cm.

8. A wafer having a uniform bulk micro defect (BMD) level in a radial direction of the wafer and including a denuded zone (DZ) of more than about 10 μm.

9. The wafer of claim 8, wherein the wafer has an oxygen concentration of more than about 11 ppma.

10. The wafer of claim 8, wherein the wafer comprises a vacancy having a size of about 80 nm to about 200 nm whose occupying percentage is more than about 40% with respect to a radius direction.
